(19) United States
(12) Patent Application Publication
(10) Pub. No.: US 2013/0086444 A1
(43) Pub. Date: Apr. 4, 2013

(54) ERROR DETECTION CODE ENHANCED SELF-TIMED/ASYNCHRONOUS NANOELECTRONIC CIRCUITS

(71) Applicant: Bao Liu, San Antonio, TX (US)

(72) Inventor: Bao Liu, San Antonio, TX (US)

(21) Appl. No.: 13/582,802

(22) PCT Filed: Mar. 4, 2011
(86) PCT No.: PCT/US11/27199

§ 371 Date: Dec. 18, 2012

Related U.S. Application Data
(60) Provisional application No. 61/310,821, filed on Mar. 5, 2010.

(51) Int. Cl. H03M 13/05; H03M 13/09; H03K 19/00

(52) U.S. Cl. CPC H03M 13/05; H03K 19/00; H03M 13/09
USPC 714/752; 326/93

(57) ABSTRACT

Provided is a system including a group of error-detecting/correcting-code self-checked/self-timed/self-corrected circuits for logic robust and performance scalable nanoelectronic design, including: (1) a combinational logic network that outputs an error-detecting/error-correcting code (EDC/ECC); and (2) an error-detecting module which gates an external clock (in a self-checked circuit), or generates an internal clock (in a self-timed circuit), and/or an error-correcting module which corrects the sequential element states (in a self-corrected circuit). Also provided is a method for implementing an error-detecting/error-correcting code (EDC/ECC) self-checked/timed/corrected circuit. The method includes (1) encoding combinational logic outputs in an error-detecting/correcting code (EDC/ECC), (2) synthesizing combinational logic, and (4) generating a gated clock in a self-checked circuit, an internal clock in a self-timed circuit, and/or corrected signals in a self-corrected circuit.

### BACKGROUND OF THE INVENTION

1. Field of the Invention

The invention generally relates to nanoelectronic circuits. More particularly, the invention relates to nanoelectronic circuits that include self-checked, self-corrected, and self-timed circuits.

2. Description of the Relevant Art

As very-large-scale integration (VLSI) technology scales into the nanometer domain, VLSI design faces unprecedented challenges in achieving manufacturability, performance, power consumption and especially, reliability. The reliability challenge arises as VLSI systems subject to increasingly prevalent catastrophic defects, soft errors, and significant parametric variations as technology scales. Process variations include lateral (transistor channel length) and vertical (gate oxide thickness) dimensional variations, dopant fluctuation, mechanical stress, etc. Accumulated process variations over time (through aging) could lead to catastrophic defects. Catastrophic defects include interconnect opens and shorts, transistor oxide breakdown, channel punch-through, etc., in the manufacturing process, which lead to permanent system malfunction. System runtime parametric variations include temperature and supply voltage degradation. Accumulated parametric variations could lead to soft errors, for example, accumulated performance degradations for each component in a signal propagation path could lead to timing violation. Soft errors are transient logic errors during system runtime induced by certain conditions, e.g., capacitive or inductive coupling noise, electromagnetic interference, alpha particle/neutron radiation or cosmos ray strikes. These may also include race/hazard-induced circuit intrinsic glitches.

Such prevalent defects, soft errors and significant parametric variations are inherent at nanometer scale (and generally cannot be reduced below certain levels) according to quantum physics. They often lead to logic malfunction, performance degradation, reliability compromise, and system lifetime reduction. Consequently, robust design techniques may be necessary and critical to successful nanoelectronic design. A redundant system may be able to tolerate catastrophic defects, a resilient system may be able to recover from soft errors, and an adaptive system may be able to tolerate parametric variations.

Robust nanoelectronic design generally need to achieve (1) logic robustness, e.g., guarantee of functional correctness in the presence of defects, soft errors, and parametric variations, and (2) performance scalability, e.g., optimized performance in the presence of performance variations. The concept of “graceful degradation” includes both logic robustness and performance scalability in the presence of performance variation.

For logic robustness, traditional fault tolerant systems typically rely on majority logic and redundancy/repetition schemes, e.g., triple module redundancy (TMR) or N-module redundancy (NMR). Modern fault tolerant systems rely mainly on error-detecting/error-correcting codes (EDCs/ECCs), which have proved themselves to be highly effective in enhancing reliability and have become integral in (1) DSM/nanometer-scale memories, and (2) wireless/on-chip communication schemes. It is believed that no EDC/ECC has been applied to digital circuit design, except that (1) a modular code has been applied in arithmatic circuits, and (2) EDCs have been applied in asynchronous circuits. (See, for example, B. Liu. Robust differential asynchronous nanoelectronic circuits. In Proc. Intl. Symp. on Quality Electronic Design, pages 97-102, 2009, which is herein incorporated by reference in its entirety). In aerospace applications where soft errors pose a significant reliability problem even in the traditional technologies, applying a code of Hamming distance 3 to combinational logic output encoding, and including the companion states (which have a Hamming distance of 1 to each legal codeword) in finite state machine (FSM) design, gives a design which tolerates all single-bit soft errors or timing violations, or, a binary code with a parity bit or a one-hot code gives a Hamming distance of two and detects any single-bit soft error.

For logic robustness against timing violations, some techniques resort to avoid timing violations by slowing down the circuit (applying a slow clock to a fast circuit). FIG. 1 depicts a Razor logic circuit 100 including combination logic 102, a multiplexer 104, a flip-flop 106, a latch (e.g., shadow latch) 108, a comparator 110, delay element 112, input 114, output 116, and cloak 118. Razor logic 100 deploys a shadow latch which captures a flip-flop input at a delayed time. A mismatch between the flip-flop output and the shadow latch output indicates a soft error or a timing violation, which is corrected by a high level system response, e.g., stalling the instruction execution for one cycle in a micro-processor pipeline, while the multiplexer takes input from the shadow latch. This circuit corrects the error at the flip-flop if the shadow latch holds the correct data, which is true at the occurrence of a setup time violation (within the range given by the clock skew between the flip-flop and the shadow latch), but not always at the occurrence of a glitch or injected noise. FIG. 2 depicts a BISER circuit 200 including a Muller-C element 120. BISER circuits extend Razor logic by including a Muller-C element, which does not change its output in the presence of any mismatch between the flip-flop and the shadow latch. However, BISER circuits fail to block all sequential elements from switching at the occurrence of a soft error or timing violation.

Asynchronous circuits achieve correct functionality in the presence of unlimited performance variations, making them useful as a performance scalable nanoelectronic design paradigm. Traditional asynchronous circuits are vulnerable to noises, which has limited their practical application for decades. A recent robust asynchronous circuit design technique applies error-detecting/correcting codes to asynchronous circuits, leading to a promising logic robust and performance scalable nanoelectronic circuit paradigm. However, hand-shaking asynchronous circuits do not have a straightforward design methodology. Moreover, they generally bear a 50% performance degradation compared with synchronous circuits (due to the back-and-forth request-and-acknowledgement communication).

Accordingly, it is desirable to provide a technique that provides circuits that are logic robust and performance scalable.

### SUMMARY OF THE INVENTION

Disclosed herein are systems and methods that provide error detecting/correcting code to self-checked/corrected/timed circuit design. In some embodiments, provided a group of error-detecting/error-correcting code (EDC/ECC) self-checked/timed/corrected circuits, including: (1) a combinational logic network that outputs an error-detecting/error-correcting-code (EDC/ECC), and (2) an error-detecting module which gates an external clock (e.g., in a self-checked circuit), or generates an internal clock (e.g., in a self-timed circuit), and/or an error-correcting module which corrects the sequential element states (e.g., in a self-corrected circuit).

In another embodiment, provided is a system including a group of error-detecting/error-correcting code (EDC/ECC) self-checked/timed/corrected circuits to implement a method for robust nanoelectronic circuit design that comprises applying error-detecting/correcting code (EDC/ECC) combinational logic output encoding, and including an error-detecting module to gate the external clock (e.g., in a self-checked circuit), or generate an internal clock (e.g., in a self-timed circuit), and/or an error-correcting module (e.g., in a self-corrected circuit).

In yet another embodiment, provided is a method for implementing an error-detecting/error-correcting code (EDC/ECC) self-checked/timed/corrected circuit. The method includes: (1) encoding combinational logic outputs in an error-detecting/correcting code (EDC/ECC), (2) synthesizing combinational logic, and (3) generating a gated clock in a self-checked circuit, an internal clock in a self-timed circuit, and/or corrected signals in a self-corrected circuit.

In another embodiment, provided is a logic stage that includes (1) a combinational logic network configured to output a delay intensive (DI) code, (2) a second combinational logic network configured to generate a clock signal, and (3) sequential elements configured to be triggered by the generated clock signal.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 depicts a Razor logic circuit;

FIG. 2 depicts a BISER circuit;

FIG. 3 depicts an error-detecting-code self-checked circuit;

FIG. 4 depicts an error-detecting-code self-timed circuit; and

FIG. 5 depicts an error-correcting-code self-corrected circuit; and

FIG. 6 depicts a Delay Insensitive (DI) code-based Domino logic self-timed circuit, or Resilient and Adaptive Performance (RAP) logic circuit.

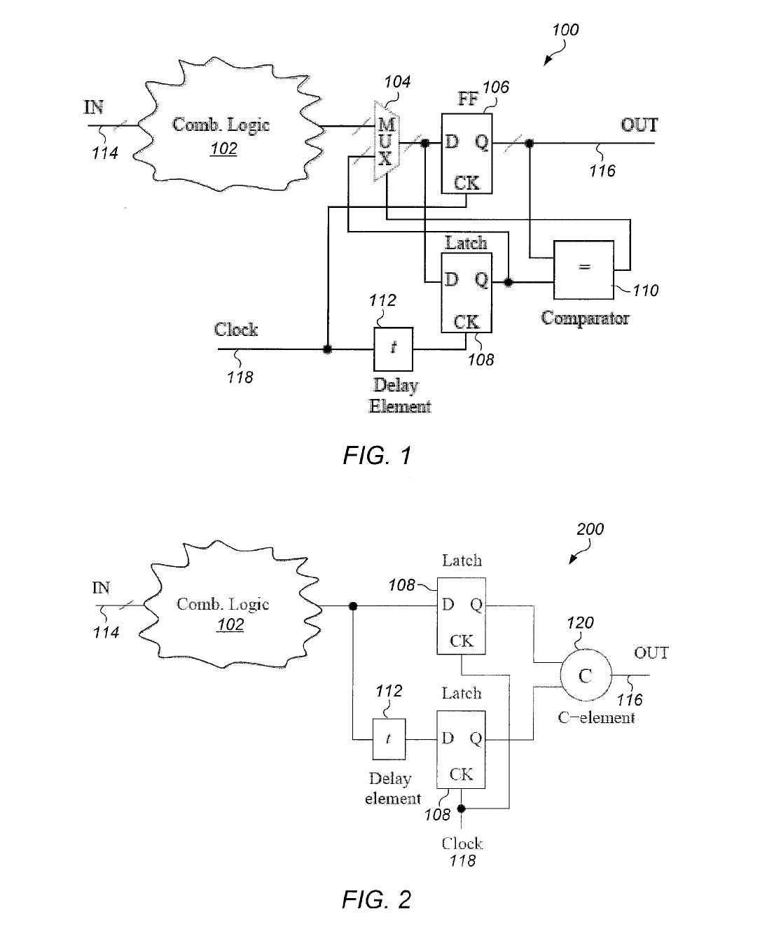

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

It is to be understood the present invention is not limited to particular devices or systems, which may, of course, vary. It is also to be understood that the terminology used herein is for the purpose of describing particular embodiments only, and is not intended to be limiting. Furthermore, note that the word “may” is used throughout this application in a permissive sense (i.e., having the potential to, being able to), not a mandatory sense (i.e., must). The term “include”, and derivations thereof, mean “including, but not limited to”. As used in this specification and the claims, the singular forms “a”, “an” and “the” include plural referents unless the content clearly indicates otherwise. Thus, for example, reference to “a circuit” includes a combination of two or more circuits. The term “coupled” means “directly or indirectly connected”.

Certain embodiments described herein relate techniques for Error Detecting/Correcting Code in self-checked/self-corrected/self-timed circuit design. In some embodiments, a circuit paradigm is sequential circuit design (EDC self-checked circuits), wherein combinational logic outputs are encoded in an Error Detecting code, while the sequential elements are triggered by a clock signal which is gated by the output of an Error-Detecting (ED) module. In some embodiments, a circuit paradigm is sequential circuit design (EDC self-timed circuits), wherein combinational logic outputs are encoded in an Error-Detecting code, while the sequential elements are triggered by an internal clock signal which is generated by the output of an Error-Detecting (ED) module and the output of a current-next-state comparator. In some embodiments, a circuit paradigm is sequential circuit design (EDC self-corrected circuits), wherein soft errors at the sequential elements are corrected by an Error-Correcting (EC) module (e.g., via a multiplexer). In these embodiments, the proposed circuits achieve improved reliability—being logic robust in the presence of any k-bit soft errors if the combinational logic outputs are encoded in an Error Detecting/Correcting Code of Hamming distance k+1 for the EDC-SC circuits. Certain embodiments (e.g., self-timed circuits) enable aggressive performance scaling in the presence of parametric variations: circuits achieve the maximum performance without causing error depending on the actual parametric variations for each chip at a specific time.

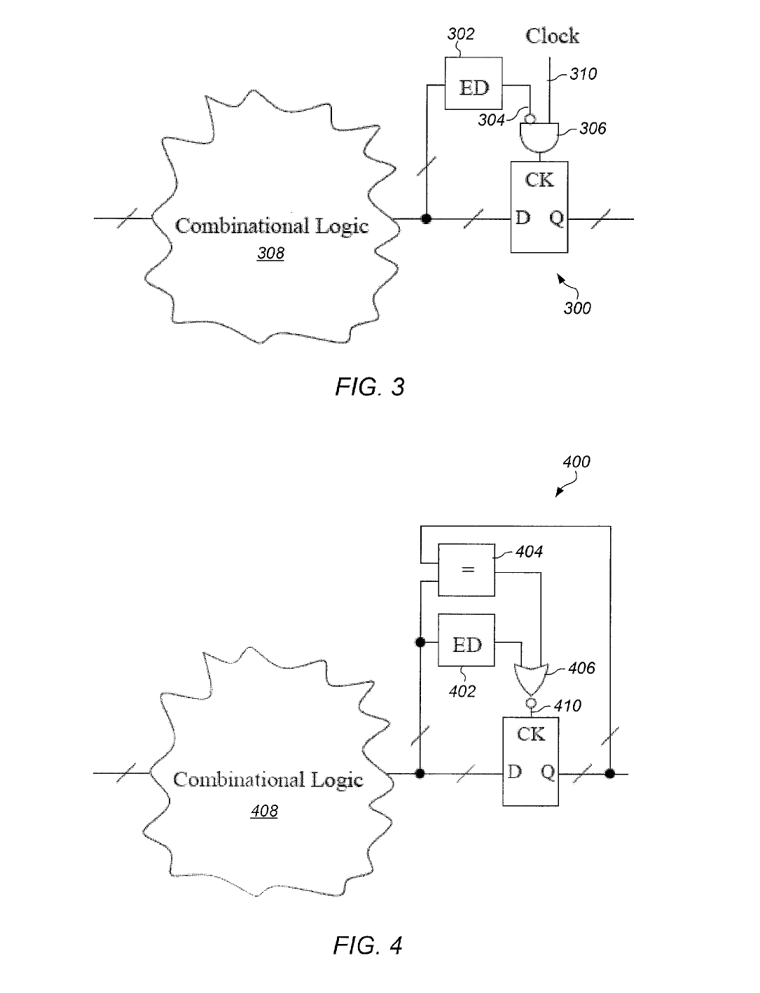

FIG. 3 depicts an error-detecting-code self-checked circuit 300, in accordance with one or more embodiments of the present technique. The illustrated embodiment includes an error-detecting (ED) module 302, an inverter 304 and an AND gate 306 which generate rising edges and triggers the sequential elements at the arrival of a valid codeword. In the illustrated embodiment, circuit 300 also includes combinational logic 308. In some embodiments, an error-detecting module gates the external clock signal 310. Upon completion of correct combinational logic computation, a valid error-detecting codeword arrives at the sequential element inputs. The error-detecting module outputs 0 and enables the external clock signal to trigger the sequential elements. At the event of soft error occurrence, an invalid codeword arrives at the sequential element inputs. The error-detecting module outputs 1 and blocks the external clock signal from triggering the sequential elements.

FIG. 4 depicts an error-correcting-code self-timed circuit 400, in accordance with one or more embodiments of the present technique. The illustrated embodiment includes an error-detecting (ED) module 402, a comparator 404, and a NOR gate 406 which generates rising edges and triggers the sequential elements at the arrival of a valid and different-than-previous codeword. In the illustrated embodiment, circuit 400 also includes combinational logic 408. In some embodiments, an error-detecting module and a current-next-state comparator generate an internal clock signal 410. Upon completion of correct combinational logic computation, a valid and different-than-previous error-correcting codeword arrives at the sequential element inputs. The error-detecting module outputs 0, the current-next-state comparator outputs 0, the NOR gate outputs a rising-edge (or an OR gate outputs a falling-edge) and triggers the sequential elements. Once the sequential elements are triggered, the sequential elements have identical input and output signals, the comparator outputs 1 and resets the clock signal. At the occurrence of a soft error in the combinational circuit, an invalid codeword arrives at the sequential element inputs, the error-detecting module outputs 1, blocking the sequential elements from capturing the incorrect inputs.

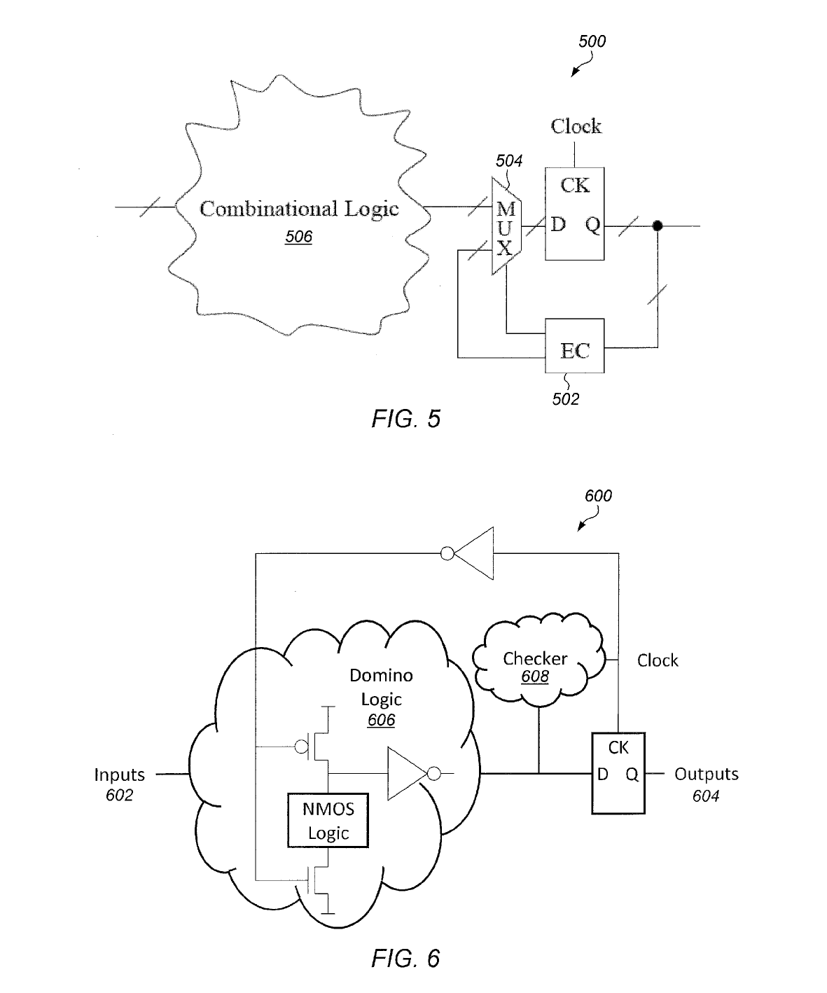

FIG. 5 depicts an error-correcting-code self-corrected circuit 500, wherein an error-correcting module corrects soft errors at the sequential elements through a multiplexer, in accordance with one or more embodiments of the present technique. The illustrated embodiment includes an error-correcting (EC) module 502 and a multiplexer 504. In the illustrated embodiment, circuit 500 also includes combinational logic 506. At the occurrence of a soft error at the sequential elements, the error-correcting module will identify and correct the error bits. The multiplexer will take input from the error-correcting module instead of from the combinational circuit. This can be taken as a direct application of the ECC schemes in memory systems to digital circuits by taking sequential elements as memory cells.

FIG. 6 depicts a Delay Insensitive (DI) code-based Domino logic self-timed circuit (or Resilient and Adaptive Performance (RAP) logic circuit) 600 in accordance with one or more embodiments of the present technique. In the illustrated embodiment, the RAP logic stage includes: (1) inputs 602 and outputs 604 encoded in DI codes, (2) a combinational logic network 606 provided in Domino logic, (3) a checker logic 608 which reads the combinational logic outputs, and triggers the sequential elements to sample only DI codewords, (4) an inverter that may be used for rising-clock-edge-triggered sequential elements or a buffer that may be used for falling-clock-edge-triggered sequential elements which pre-charges the Domino logic network, and (5) sequential elements. RAP logic may work as follows: (1) a complete logic computation provides a codeword, (2) the checker outputs a rising clock edge, (3) the sequential elements latch the data and output high voltage, (4) the Domino logic pre-charges, (5) the Domino logic outputs return to zero, (6) the checker outputs a falling clock edge, and (7) the Domino logic evaluates. Such a RAP logic stage may form a synchronous module, such as a Finite State Machine (FSM), in a synchronous or Globally-Asynchronous-Locally-Synchronous (GALS) system. Compared with the traditional synchronous design of an external fixed clock signal and a CMOS static logic network, RAP logic may provide (1) adaptive performance, and (2) soft error resilience with reduced hardware overhead. In Domino logic, only the inverters may need to be sized-up, while in a CMOS static logic, all logic gates for soft error resilience may need to be sized up. Notably, dynamic logic stages generate only uni-directional faults which are detectable by the checker logic. When compared with certain traditional Domino logic, RAP logic may achieve layout area reduction and performance improvement. Traditional dual-rail Domino logic (DCVSL) typically achieves error detec double-rail code. An n-bit double-rail codeword includes n/2 information bits, and n/2 complement ting capability and adaptive performance based on specific Delay-Insensitive code, such as ary bits. Consequently, it contains n/2 bits of logic one, and n/2 bits of logic zero. In such a delay insensitive code, half of the codeword bits are redundant. Notably, other DI codes may be more efficient, for example, for a codeword length of n, a Berger codeword includes log(n) redundant bits.

Several variant circuits exist. For example, circuits 300, 400 and 500 of FIGS. 3-5 can be combined.

A number of error-detecting/correcting codes are available for combinational logic output encoding (See, for example, T. K. Moon. Error Correction Coding: Mathematical Methods and Algorithms. Wiley-Interscience, 2005, which is herein incorporated by reference in its entirety). The Hamming distance of an errordetecting/correcting code gives the maximum number of soft error bits that can be detected/corrected. For example, the parity code (including an overall parity bit in a binary code) is able to detect a single bit soft error or an odd number of bits of soft error. The (7,4) Hamming code is able to correct any single bit soft error and detect any double bit soft error. The extended (7,4) Hamming code (including an additional overall parity bit in a (7,4) Hamming code) is able to distinguish single bit and double bit soft errors, correct any single bit soft error and detect any double bit soft error. In general, n-bit data encoded in an errordetecting/correcting code of n+k+1 bits with a Hamming distance k+1 is immune to any k-bit soft error (See, for example, T. K. Moon. Error Correction Coding: Mathematical Methods and Algorithms. Wiley-Interscience, 2005).

A (k+m,k) Hamming code (e.g., see Table I below—The (7,4) Hamming Code) includes k information bits u and m check bits p. The check bits p are located in the positions of power-of-two's (1, 2, 4, 8, 16, . . . ). p0 is the parity bit for bits at the odd positions (1, 3, 5, 7, . . . ). p1 is the parity bit for bits in the positions which have a 1 in their second from least significant bit in their binary representations (2, 3, 6, 7, . . . ). p2 is the parity bit for bits in the positions which have a 1 in their third from least significant bit in their binary representations (4, 5, 6, 7, . . . ). The syndrome or the error indicator is calculated by exclusive or (XOR) of the bits in the same groups, e.g., in the odd positions, in the (2, 3, 6, 7, . . . ) positions, in the (4, 5, 6, 7, . . . ) positions, and so on. Any single bit error is indicated by the syndrome, and corrected accordingly.

TABLE I

| | 1 | 2 | 3 | 4 | 5 | 6 | 7 |
|---|---|---|---|---|---|---|---|
| Information | p₀ | p₁ | u₃ | p₂ | u₂ | u₁ | u₀ |
| 0 | 0 | 0 | 0 | 0 | 0 | 0 | 0 |
| 1 | 1 | 1 | 0 | 1 | 0 | 0 | 1 |
| 2 | 0 | 1 | 0 | 1 | 0 | 1 | 0 |
| 3 | 1 | 0 | 0 | 0 | 0 | 1 | 1 |
| 4 | 1 | 0 | 0 | 1 | 1 | 0 | 0 |
| 5 | 0 | 1 | 0 | 0 | 1 | 0 | 1 |
| 6 | 1 | 1 | 0 | 0 | 1 | 1 | 0 |
| 7 | 0 | 0 | 0 | 1 | 1 | 1 | 1 |
| 8 | 1 | 1 | 1 | 0 | 0 | 0 | 0 |
| 9 | 0 | 0 | 1 | 1 | 0 | 0 | 1 |
| 10 | 1 | 0 | 1 | 1 | 0 | 1 | 0 |
| 11 | 0 | 1 | 1 | 0 | 0 | 1 | 1 |
| 12 | 0 | 1 | 1 | 1 | 1 | 0 | 0 |
| 13 | 1 | 0 | 1 | 0 | 1 | 0 | 1 |
| 14 | 0 | 0 | 1 | 0 | 1 | 1 | 0 |
| 15 | 1 | 1 | 1 | 1 | 1 | 1 | 1 |

Including an additional bit for the overall parity of the codeword gives an extended Hamming code, which is a single-error-correcting double-error-detecting (SEC-DED) code. The code has no error if the overall parity bit and the syndrome are both 0. If the overall parity bit is 1, the syndrome gives the single bit error position (except that an all 0 syndrome indicates that the overall parity bit needs to be corrected). If there are two bits of error, the overall parity bit is 0, while the syndrome is not 0.

An error-detecting (ED) module in a Hamming code circuit includes a syndrome generator (which checks the sequential element inputs) and an OR gate (which takes as inputs the syndrome generator output and the overall parity bit). A 0 ED module output and a 0 comparator output (the current codeword is not identical with the previous codeword) trigger the sequential elements (through a NOR gate for rising-edge-triggered sequential elements or through an OR gate for falling-edge-triggered sequential elements).

An error-correcting (EC) module includes another syndrome generator (which checks the sequential element outputs). The syndrome is decoded as a binary address to correct the error bit at one of the sequential elements. The (7,4) Hamming code has a Hamming distance of three and a transitional Hamming distance of one. When no logic computation is taking place, at least three bits need to be toggled at the sequential element inputs to cause the latching of an unintended codeword. When a logic computation is taking place, toggling of a single bit at the sequential element inputs suffices to latch in an unintended codeword, e.g., during a transition from 0000000 to 0001111, a single-bit toggling from 0000101 leads to 0100101, which is another legal codeword.

A successful EDC/ECC self-checked/timed/corrected circuit design may prevent the occurrence of an unintended codeword at the sequential element inputs under the combined effects of (1) soft errors (including circuit intrinsic glitches), and (2) performance variations (e.g., any partial transition between two valid codewords does not lead to an unintended codeword).

Several techniques help to achieve logic robustness:
1. Combinational logic output encoding needs to maximize the Hamming distance (the distance between two stable codewords) in a self-checked or self-corrected circuit. In a self-timed circuit, combinational logic output encoding also needs to maximize the “transitional Hamming distance” (the distance between two transient codewords).
2. The maximum combinational fanout (the maximum fanout in the combinational circuit, excluding primary inputs, primary outputs, sequential element outputs, the error-correcting module, the associated multiplexer, the error-detecting module, and the current-next-state comparator) may need to be limited, e.g., by (1) duplicating parts of the combinational circuit, (2) optimizing the combinational circuit for performance (which leads to a wide and shallow netlist), and (3) inserting additional flip-flops (increasing pipeline stages) such that the high fanout nets become sequential element outputs which reliability is enhanced by EDC/ECC.

Logic robustness is achieved as follows.
1. To guarantee logic correctness in the presence of a single bit soft error in the combinational circuit, the maximum combinational fanout may need to be smaller than the Hamming distance if no performance variation is present, or the transitional Hamming distance if performance variation is present.
2. The error-detecting module and the error-correcting module enhance signal reliability at the sequential element outputs.
3. A soft error at the error-correcting module may be corrected subsequently since it does not lead to another valid codeword (e.g., the error-correcting module only corrects a single bit at a time).
4. A soft error at the error-detecting module may lead to a false error (a valid codeword which is identified as invalid, such that the sequential elements do not take it until the soft error subsides), which is acceptable; or, a missing error (an invalid codeword which is identified as valid), which may need to be avoided (e.g., by deploying multiple error-detecting modules).
5. A soft error at the current-next-state comparator in a self-timed circuit may lead to a false inequality (such that the sequential elements are triggered unnecessarily), which may lead to power consumption increase but no logic error; or a false equality (which prevents the sequential elements from capture the data), which may need to be avoided (e.g., by deploying multiple comparators).
6. A soft error at the clock is unlikely due to the large capacitance of a clock net. While the clock gates (the AND gate in FIG. 3 and the NOR gate in FIG. 4) may need to be duplicated, and a sequential element with multiple clocks may be more reliable.

In comparison, triple module redundancy (TMR) achieves the same level of reliability as the (7,4) Hamming self-corrected circuit (correcting any single bit soft error or timing violation), but with more transistors (e.g., 10 more transistors for this example if a flip-flop is implemented in 20 transistors). In fact, TMR is the simplest Hamming code—the (3,1) Hamming code. Other (e.g., (15, 11), (31, 26) and so on) Hamming codes are increasingly more efficient, require less check bits hence hardware overhead per information bit.

A Razor circuit may only guarantee to correct a setup timing violation within a given timing window. A BISER circuit may fail to block all sequential elements from sampling at the occurrence of a soft error.

A hand-shaking protocol based asynchronous circuit achieves the same performance scalability as an equivalent self-timed circuit in the presence of parametric variations. Both performances are time-varying and given by the slowest combinational logic computation in the circuit in a specific time frame, while the performance of a synchronous circuit is fixed and given by the slowest combinational logic computation in the circuit in all time. However, an asynchronous circuit achieves at most half of the performance achievable by an equivalent self-timed or synchronous circuit (due to the communication cost of the hand-shaking protocol). Furthermore, hand-shaking protocol based asynchronous circuits do not have a straightforward design methodology.

Based on the above, a group of EDC/ECC self-checked/timed/corrected circuits are proposed. Embodiments include applying EDC/ECC in general digital circuit design. In some embodiments, a TMR of the proposed circuits may include reduced (e.g., the least) efficiency or increased (e.g., the maximum) hardware overhead for reliability. Existing performance scalable (Razor and BISER) circuits achieve less reliability. Embodiments that include the straightforward design methodology gives the proposed EDC/ECC self-checked/timed/corrected circuits an extra edge compared with hand-shaking asynchronous EDC/ECC circuits.

In some embodiments, a self-checked circuit (e.g., see FIG. 3) includes:
(a) a combinational logic network which provides one or more outputs including an error-detecting (e.g., parity) code,
(b) an error-detecting (ED) module which checks if the combinational logic outputs include a valid codeword,
(c) a second combinational logic network (e.g., an inverter and an AND gate or a NAND gate or an OR gate or a NOR gate) which gates the external clock, and
(d) sequential elements which are triggered by the gated clock.

In some embodiments, a self-timed circuit (e.g., see FIG. 4) includes:
(a) a combinational logic network which provides one or more outputs including an error-detecting (e.g., parity) code,
(b) an error-detecting (ED) module which checks if the combinational logic outputs include valid codeword,
(c) a comparator which checks if the sequential element inputs are identical with the sequential element outputs, and
(d) another combinational logic network (e.g., an OR gate or a NOR gate) which generates an internal clock signal based on the ED module and the comparator, and
(e) sequential elements which are triggered by the internal clock.

In some embodiments, a self-corrected circuit (e.g., see FIG. 5) includes:
(a) a combinational logic network which provides one or more outputs including an error correcting (e.g., Hamming or extended Hamming (with an overall parity bit)) code, and
(b) an error-correcting (EC) module, which checks the sequential element outputs and corrects the sequential element states if the states are not a valid codeword (e.g., by a multiplexer).

In some embodiments, a self-checked and self-corrected circuit includes:
(a) a combinational logic network which provides one or more outputs including an error-detecting (e.g., parity) code,
(b) an error-detecting (ED) module which checks if the combinational logic outputs include a valid codeword,
(c) another combinational logic network (e.g., an inverter and an AND gate or a NAND gate or an OR gate or a NOR gate) which gates the external clock,
(d) sequential elements which are triggered by the gated clock, and
(e) an error-correcting (EC) module, which checks the sequential element outputs and corrects the sequential element states if the states are not a valid codeword (e.g., by a multiplexer).

In some embodiments, a self-timed and self-corrected circuit includes:
(a) a combinational logic network which provides one or more outputs including an error-correcting (e.g., Hamming or extended Hamming (with an overall parity bit)) code,
(b) an error-detecting (ED) module which checks if the combinational logic outputs include a valid codeword,
(c) a comparator which checks if the sequential element inputs are identical with the sequential element outputs,
(d) another combinational logic network (e.g., an OR gate or a NOR gate) which generates an internal clock signal based on the ED module and the comparator, and
(e) sequential elements which are triggered by the internal clock, and
(f) an error-correcting (EC) module, which checks the sequential element outputs and corrects the sequential element states if the states are not a valid codeword (e.g., by a multiplexer).

In some embodiments, a self-checked and double self-corrected circuit includes:
(a) a combinational logic network which provides one or more outputs including an error-detecting (e.g., parity) code,
(b) an error-detecting (ED) module which checks if the combinational logic outputs include a valid codeword,
(c) another combinational logic network (e.g., an inverter and an AND gate or a NAND gate or an OR gate or a NOR gate) which gates the external clock,
(d) sequential elements which are triggered by the gated clock, and
(e) an error-correcting (EC) module, which checks the sequential element outputs and corrects the sequential element states if the states are not a valid codeword (e.g., by a multiplexer), and
(f) a second error-correcting (EC′) module, which checks the combinational logic circuit outputs and generates corrected codeword at the sequential element inputs.

In some embodiments, a self-timed and double self-corrected circuit includes:
(a) a combinational logic network which provides one or more outputs including an error-correcting (e.g., Hamming or extended Hamming (with an overall parity bit)) code,
(b) an error-detecting (ED) module which checks if the combinational logic outputs include a valid codeword,
(c) a comparator which checks if the sequential element inputs are identical with the sequential element outputs,
(d) another combinational logic network (e.g., an OR gate or a NOR gate) which generates an internal clock signal based on the ED module and the comparator, and
(e) the sequential elements which are triggered by the internal clock,
(f) an error-correcting (EC) module, which checks the sequential element outputs and corrects the sequential element states if the states are not a valid codeword (e.g., by a multiplexer), and
(g) a second error-correcting (EC′) module, which checks the combinational logic circuit outputs and generates corrected codeword at the sequential element inputs.

In some embodiments, a Delay Insensitive (DI) code and inverter-free (e.g., Domino) logic-based Resilient and Adaptive Performance (RAP) logic stage (e.g., see FIG. 6) includes:
(a) a combinational logic network which provides one or more outputs including a DI code,
(b) a second combinational logic network which generates a clock signal, e.g., the clock signal rises/falls at the detection of a DI code as a result of combinational logic computation, and
(c) sequential elements which are triggered by the generated clock signal.

In some embodiments, the data stored in a memory is encoded in a Delay Insensitive (e.g., Berger or Sperner) code, such that a completion signal is generated for a memory operation (e.g., read/write).

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

In this patent, certain U.S. patents, U.S. patent applications, and/or other materials (e.g., articles) have been incorporated by reference. The text of such U.S. patents, U.S. patent applications, and other materials is, however, only incorporated by reference to the extent that no conflict exists between such text and the other statements and drawings set forth herein. In the event of such conflict, then any such conflicting text in such incorporated by reference U.S. patents, U.S. patent applications, and other materials is specifically not incorporated by reference in this patent.

1. A system comprising a group of error-detecting/error-correcting code (EDC/ECC) self-checked/timed/corrected circuits, comprising:
(1) a combinational logic network that outputs an error-detecting/error-correcting-code (EDC/ECC); and
(2) an error-detecting module that gates an external clock or generates an internal clock, and/or an error-correcting module that corrects the sequential element states.

2. The system of claim 1, wherein the external clock is gated in a self-checked circuit.

3. The system of claim 1, wherein the internal clock is generated in a self-timed circuit.

4. The system of claim 1, wherein the sequential element states are corrected in a self-corrected circuit.

5. A system, comprising:
a group of error-detecting/error-correcting code (EDC/ECC) self-checked/timed/corrected circuits configured to implement a method for robust nanoelectronic circuit design that comprises applying error-detecting/error-correcting code (EDC/ECC) combinational logic output encoding; and an error-detecting module configured to gate the external clock, or generate an internal clock, and/or an error-correcting module.

6. The system of claim 5, wherein the external clock is gated in a self-checked circuit.

7. The system of claim 5, wherein the internal clock is generated in a self-timed circuit.

8. The system of claim 5, wherein the sequential element states are corrected in a self-corrected circuit.

9. The system of claim 5, wherein the error-detecting module is provided as part of one or more of the circuits, or separate from one or more of the circuits.

10. A method for implementing an error-detecting/error-correcting code (EDC/ECC) self-checked/timed/corrected circuit, comprising:
(1) encoding combinational logic outputs in an error-detecting/correcting code (EDC/ECC);
(2) synthesizing combinational logic; and
(3) generating a gated clock in a self-checked circuit, an internal clock in a self-timed circuit, and/or corrected signals in a self-corrected circuit.

11. The method of claim 10, wherein an input includes logic specification, robust and performance scalable requirements, and wherein an output includes logic implementation meeting the logic specification, robust and performance scalable requirements.

12. A logic stage, comprising:
(1) a combinational logic network configured to output a delay intensive (DI) code,
(2) a second combinational logic network configured to generate a clock signal, and
(3) sequential elements configured to be triggered by the generated clock signal.

13. The logic stage of claim 12, wherein the clock signal rises/falls at the detection of a DI code as a result of combinational logic computation.

14. (canceled)

15. (canceled)
